(19) United States
(12) Patent Application Publication
(10) Pub. No.: US 2003/0008499 A1
(43) Pub. Date: Jan. 9, 2003

(54) Method of manufacturing semiconductor device and semiconductor device

(75) Inventor: Heiji Kobayashi, Hyogo (JP)

Correspondence Address: McDERMOTT & WILL & EMERY, 600 13th Street, N.W., Washington, DC, 20005-3096, US

(73) Assignee: Mitsubishi Denki Kabushiki Kaisha

(21) Appl. No.: 10/135,514

(22) Filed: May 1, 2002

(30) Foreign Application Priority Data
Jul. 9, 2001 (JP) 2001-207543(P)

(51) Int. Cl. H01L 21/8242; H01L 21/20; H01L 21/261; H01L 21/4763

(52) U.S. Cl. 438/637; 438/246; 438/389; 438/512; 438/914

(57) ABSTRACT

According to the present method of manufacturing a semiconductor device, since a contact hole has its opening gradually and continuously made smaller toward the lower interconnection layer, a cavity, which has been produced conventionally, would not be produced in a barrier metal layer and a metal interconnection layer formed along the side wall of the contact hole. As a result, even when the reduction in size of the semiconductor has progressed, it is possible to provide a method of manufacturing semiconductor device having its contact hole in a proper shape, and to provide such a semiconductor device.

### BACKGROUND OF THE INVENTION

1. Field of the Invention

The present invention relates to a semiconductor device and a method of manufacturing the same, and more specifically to a semiconductor device which contemplates improving the shape of a contact hole, and a method of manufacturing the same.

2. Description of the Background Art

With reference to FIG. 7, a conventional interconnection structure using a contact hole between a lower interconnection layer and buried interconnection layers of a semiconductor device having the contact hole will be described. An interlayer insulating layer 2 is formed on a lower interconnection layer 1. The interlayer insulating layer 2 is provided with a contact hole 2a which is provided with a barrier metal layer 3 and metal interconnection layer 4 as buried interconnection layers, which are electrically connected to the lower interconnection layer 1.

In the structure of the contact hole described above, however, the shape of the contact hole tends to be degraded, due to recent requirements for reducing the size of semiconductor devices. The shape illustrated in FIG. 7 is also degraded, with the middle portion of the contact hole bulging outward (in bowing shape). Forming buried interconnection layers 3 and 4 with the contact hole being in the bowing shape results in formation of a cavity 4a, as shown. When the cavity 4a is formed, water or chemical processing liquid may get into or remain in the cavity, which might degrade electrical characteristics of the buried interconnection layers 3 and 4 in the contact hole.

### SUMMARY OF THE INVENTION

The object of the present invention is to provide a semiconductor device having a contact hole of a proper shape even when the size of the semiconductor device is reduced, and a method of manufacturing the same.

A method of manufacturing a semiconductor device according to the present invention includes the steps of: forming a lower interconnection layer; forming an interlayer insulating layer on the lower interconnection layer; forming a contact hole in the interlayer insulating layer which reaches the lower interconnection layer; and forming buried interconnection layers in the contact hole which are connected to the lower interconnection layer, wherein the step of forming the contact hole includes the steps of introducing an impurity into the interlayer insulating layers, and etching the interlayer to which the impurity has been introduced.

A semiconductor device according to the present invention includes a lower interconnection layer, an interlayer insulating layer which is provided on the lower interconnection layer, a contact hole which is provided in the interlayer insulating layer and which reaches the lower interconnection layer, and buried interconnection layers which are provided in the contact hole and which are connected to the lower interconnection layer, wherein the contact hole is provided such that its opening gradually and continuously becomes smaller toward the lower interconnection layer.

According to the semiconductor device and the method of manufacturing the same as described above, a cavity would not be produced in the buried interconnection layers which are formed along the side wall of the contact hole, since the shape of the contact hole is such that its opening gradually and continuously becomes smaller toward the lower interconnection layer. Thus, it becomes possible to maintain the reliability of the electric characteristics of the buried interconnection layers.

Further, in the method of manufacturing the semiconductor device, it is preferable that the step of etching employs wet etching for etching the interlayer insulating layer. Thus, it becomes possible to remove the interlayer insulating layer of the upper region of the contact hole which is in bowing shape, thereby rendering the shape of the opening of the contact hole gradually smaller toward the lower interconnection layer.

Further, in the method of manufacturing the semiconductor device, more preferably, the impurity to be introduced into the interlayer insulating layer is boron, and the step of performing etching process on the interlayer insulating layer is performed using ammonia-hydrogen peroxide aqueous solution. Further, in the method of manufacturing a semiconductor device, it is more preferable that the impurity to be introduced into the interlayer insulating layer is phosphorus, and the step of performing etching process on the interlayer insulating layer is performed using hydrofluoric acid. Further, in the method of manufacturing the semiconductor device, it is more preferable that the process of etching employs an isotropic dry etching process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a structure of a semiconductor device in the first embodiment.

FIGS. 2 to 4 are first to third cross-sectional views illustrating manufacturing steps of a semiconductor device in the first embodiment.

FIGS. 5 and 6 are first and second cross-sectional views illustrating manufacturing steps of a semiconductor device in the first embodiment.

FIG. 7 is a cross-sectional view illustrating a structure of a semiconductor device of the prior art.

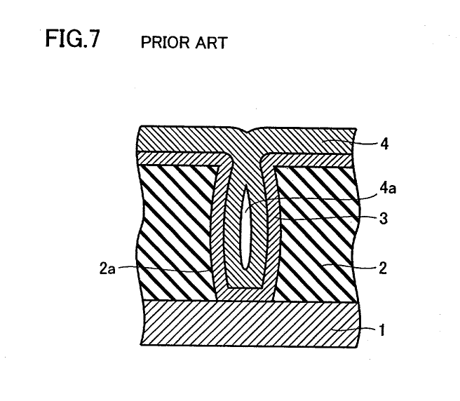

### DESCRIPTION OF THE PREFERRED EMBODIMENTS

Referring to the figures, a semiconductor device in each embodiment according to the present invention and a method of manufacturing the same will now be described below.

### First Embodiment

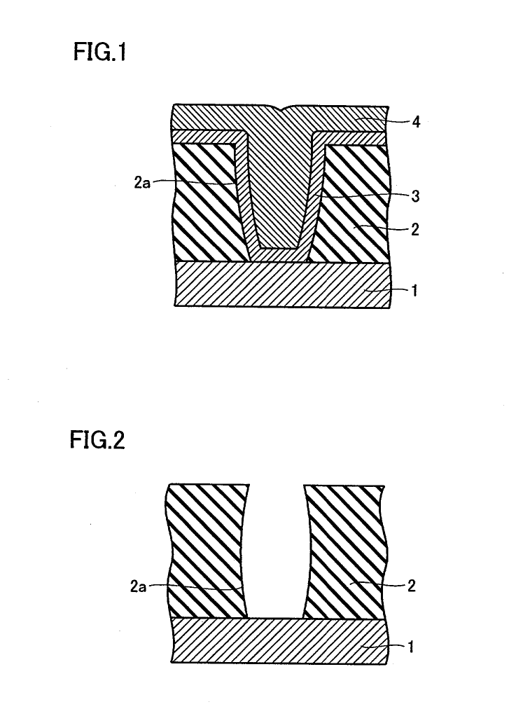

Referring to FIGS. 1 to 4, a semiconductor device and a method of manufacturing the same in an embodiment of the present invention will be described.

### Semiconductor Device

Referring to FIG. 1, an interlayer insulating layer 2 is formed on a lower interconnection layer 1 which is formed of a conductive material. The lower interconnection layer 1 may be a semiconductor substrate such as a silicon substrate. The interlayer insulating layer 2 is provided with a contact hole 2a. This contact hole 2a is provided such that its opening gradually and continuously becomes smaller toward the lower interconnection layer 1. At the contact hole, a barrier metal layer 3 and a metal interconnection layer 4 are provided as buried interconnection layers which are electrically connected to the lower interconnection layer 1. TiN is used as a barrier metal layer 3 and W or the like is used as a metal interconnection layer 4.

### Method of Manufacturing Semiconductor Device

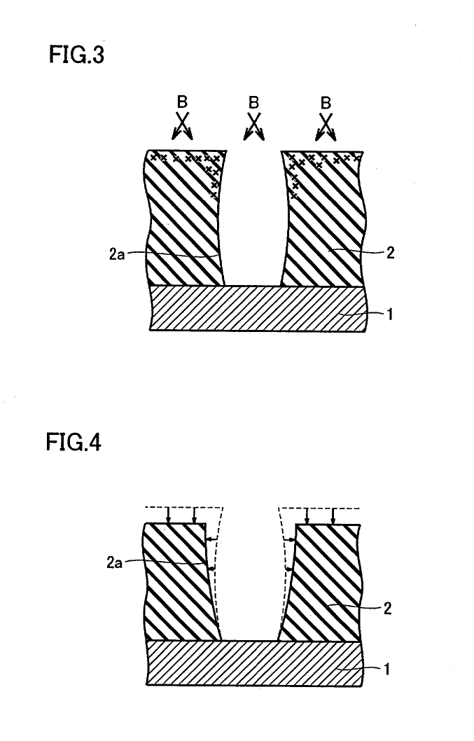

Next, a method of manufacturing a semiconductor device having the structure above will be described referring to FIGS. 2 to 4. First, referring to FIG. 2, the interlayer insulating layer 2 of TEOS or the like is formed on the lower interconnection layer 1, and the contact hole 2a is formed in the interlayer insulating layer 2 using a mask formed by photolithography technology. The middle portion of this contact hole 2a is bulging outward (in bowing shape), as illustrated.

Then, referring to FIG. 3, an impurity is introduced into the interlayer insulating layer 2 by oblique ion rotational implantation. Possibly impurity includes boron, phosphorus or the like. The purpose of introducing ions using the oblique ion rotational implantation is to introduce ion onto the surface of the interlayer insulating layer 2 and into an upper region of the contact hole 2a only, as illustrated, and not to introduce ions into a bottom region of the contact hole 2a.

Then, referring to FIG. 4, an etching process of the interlayer insulating layer 2 is performed by wet etching. When the impurity which is introduced into the interlayer insulating layer 2 is boron, wet etching is performed using ammonia-hydrogen peroxide aqueous solution (NH₄OH;H₂O₂;H₂O: APM). When the impurity which is introduced into the interlayer insulating layer 2 is phosphorous, wet etching is performed using hydrofluoric acid (HF). By this wet etching process, the region to which ions have been introduced from the above step is preferentially removed by etching, thereby rendering the shape of the opening of the contact hole 2a gradually and continuously smaller toward the lower interconnection layer 1.

Thereafter, the barrier metal layer 3 of TiN or the like is formed along the shape of the contact hole 2a, and further the metal interconnection layer 4 of W or the like is deposited on the barrier metal layer 3. This completes the semiconductor device illustrated in FIG. 1.

### Effects of the Invention

From the foregoing, according to the semiconductor device and the method of manufacturing the same of the present embodiment, since the shape of the contact hole 2a is such that its opening gradually and continuously becomes smaller toward the lower interconnection layer 1, a cavity, which is produced conventionally, would not be produced in the barrier metal layer 3 and the metal interconnection layer 4 formed along the side wall of the contact hole 2a. This enables maintenance of the reliability of the electric characteristics of the metal interconnection layer 4.

Further, in the step of the etching process, selecting the etchant that is adopted to the ion species allows the region to which ions have been implanted to be preferentially removed by etching, thereby rendering effectively the shape of the opening of the contact hole 2a gradually smaller toward the lower interconnection layer 1.

### Second Embodiment

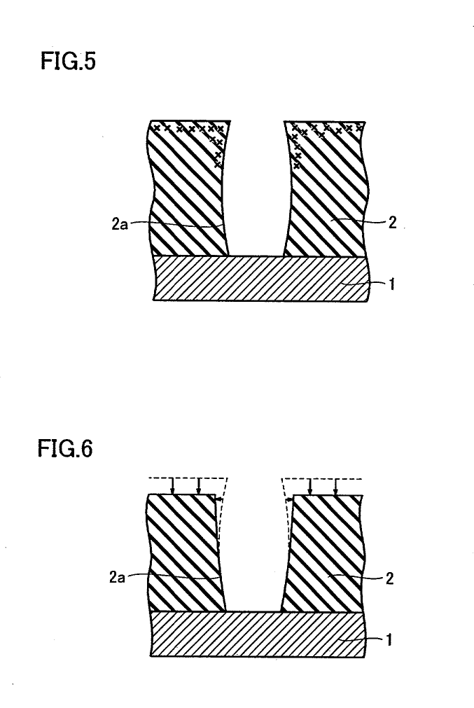

Next, a semiconductor device and a method of manufacturing the same of the present embodiment will now be described referring to FIGS. 5 and 6. FIGS. 5 and 6 are cross-sectional views illustrating the steps of manufacturing the semiconductor device in the present embodiment.

Since the characteristic of the present embodiment lies in the method of manufacturing a semiconductor device, only the difference between the first embodiment and the present embodiment will be described, referring to the drawings. In the present embodiment, first referring to the FIG. 5, an impurity is introduced into the interlayer insulating layer 2, of which middle portion is bulging outward (in bowing shape), by oblique ion rotational implantation similar to the above embodiment. Possibly impurity includes boron, phosphorus or the like. The purpose of using oblique ion rotational implantation to implant ion is same as the first embodiment.

Then, referring FIG. 6, etching process is performed on the interlayer insulating layer 2 by dry etching (isotropic etching) under condition in which an isotropic component is strong. Here, in isotropic dry etching, the condition in which the isotropic component is strong means that a microloading effect is strong, and therefore etching would not proceed in the bottom region of the contact hole 2a.

By this dry etching process, the region to which ions have been implanted in the above process are preferentially removed by etching, thereby rendering the shape of the opening of the contact hole 2a gradually and continuously smaller toward the lower interconnection layer 1, as described in the first embodiment. The following process is the same as described in the first embodiment.

### Effects of the Invention

From the foregoing, according to the present embodiment of the semiconductor device and the method of manufacturing the same, by combining the ion implantation step and the isotropic etching process, the region to which ions have been implanted is preferentially removed by etching, thereby rendering the shape of the opening of the contact hole 2a gradually and continuously smaller toward the lower interconnection layer 1 further effectively.

As a result, a cavity, which has been produced conventionally, would not be produced in the barrier metal layer 3 and the metal interconnection layer 4 formed along the side wall of the contact hole 2a. This enables maintenance of the reliability of the electric characteristic of the metal interconnection layer 4.

Semiconductor devices to which the present invention is applicable includes DRAM, SRAM, MRAM, FeRAM, EEPROM, eRAM and the like.

According to the method of manufacturing semiconductor device and the semiconductor device of the present invention, since the contact hole is has its opening gradually and continuously made smaller toward the lower interconnection layer 1, a cavity would not be produced in the buried layers formed along the side wall of the contact hole. This enables maintenance of the reliability of the electric characteristics of the buried interconnection layers.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device, comprising the steps of:
forming a lower interconnection layer;
forming an interlayer insulating layer on said lower interconnection layer;
forming a contact hole in said interlayer insulating layer reaching said lower interconnection layer; and
forming buried interconnection layers connected to said lower interconnection layer in said contact hole;
wherein the step of forming said contact hole has
introducing an impurity into said interlayer insulating layer by oblique ion rotational implantation, and
etching said interlayer insulating layer doped with the impurity.

2. The method of manufacturing a semiconductor device according to claim 1, wherein
the step of etching said interlayer insulating layer employs wet etching.

3. The method of manufacturing a semiconductor device according to claim 2, wherein
the impurity introduced into said interlayer insulating layer is boron, and etching of said interlayer insulating layer is performed using ammonia-hydrogen peroxide aqueous solution.

4. The method of manufacturing a semiconductor device according to claim 2, wherein
the impurity introduced into said interlayer insulating layer is phosphorous, and etching of said interlayer insulating layer is performed using hydrofluoric acid.

5. The method of manufacturing a semiconductor device according to claim 2, wherein
said step of etching employs isotropic dry etching.

6. A semiconductor device, comprising:
a lower interconnection layer;
an interlayer insulating layer provided on said lower interconnection layer;
a contact hole formed in said interlayer insulating layer and reaching said lower interconnection layer; and
buried interconnection layers provided in said contact hole and connected to said lower interconnection layer; wherein
said contact hole is provided such that its opening gradually and continuously becomes smaller toward said lower interconnection layer.
